(19) United States
(12) Patent Application Publication
(10) Pub. No.: US 2017/0107616 A1
(43) Pub. Date: Apr. 20, 2017

(54) Method of Fabricating Semiconductor Device and Method of Cleaning Processing Chamber in Semiconductor Device

(71) Applicant: Samsung Electronics Co., Ltd., Suwon-si (KR)

(72) Inventors: Bo-young SHIM, Hwaseong-si (KR); Eun-sung KIM, Seoul (KR); Chul-hwan CHOI, Seoul (KR); Chung-hwan KIM, Hwaseong-si (KR)

(21) Appl. No.: 15/262,544

(22) Filed: Sep. 12, 2016

(30) Foreign Application Priority Data
Oct. 20, 2015 (KR) 10-2015-0146096

(51) Int. Cl. C23C 16/455; B08B 15/00; B08B 7/00; B08B 9/08; H01L 21/033; B08B 5/00

(52) U.S. Cl. CPC C23C 16/45525; H01L 21/0332; H01L 21/0337; B08B 5/00; B08B 7/0035; B08B 9/08; B08B 15/00; H01L 21/0214

(57) ABSTRACT

Provided are a method of fabricating a semiconductor The method of fabricating a semiconductor device includes: transporting a substrate having a carbon-based sacrificial layer pattern to a processing chamber; forming a mask material layer on the substrate; removing the substrate from the processing chamber; and removing at least a part of a carbon-based material layer formed inside the processing chamber.

### CROSS-REFERENCE TO RELATED APPLICATION

This application claims the benefit of Korean Patent Application No. 10-2015-0146096, filed on Oct. 20, 2015, in the Korean Intellectual Property Office, the disclosure of which is incorporated herein in its entirety by reference.

### BACKGROUND

The inventive concept relates to a method of fabricating a semiconductor device and a method of cleaning a processing chamber in the semiconductor device, and more particularly, to a method of increasing a yield rate of a semiconductor device by improving process quality of the semiconductor device.

A double patterning technology (DPT) process and a quarter patterning technology (QPT) process include a plurality of atomic layer deposition (ALD) processes. Quality of a fabricated product may deteriorate due to interference between the processes, and thus, there is a need to resolve the interference.

### SUMMARY

The inventive concept provides a method of fabricating a semiconductor having improved process quality and increased yield rate.

The inventive concept provides a method of cleaning a semiconductor in a processing chamber so as to improve process quality and yield rate of the semiconductor.

According to an aspect of the inventive concept, provided is a method of fabricating a semiconductor device, the method including: transporting a substrate having a carbon-based sacrificial layer pattern to a processing chamber; forming a mask material layer on the substrate; removing the substrate from the processing chamber; and removing at least a part of a carbon-based material layer formed inside the processing chamber.

According to another aspect of the inventive concept, provided is a method of cleaning a processing chamber for fabricating a semiconductor device, the method including: removing silicon oxide inside the processing chamber for fabricating a semiconductor device; removing an organic material inside the processing chamber for fabricating a semiconductor device; and purging impurities generated during the removing of the silicon oxide and the removing of the organic material, wherein the purging discharges the impurities from the processing chamber.

According to yet another aspect of the inventive concept, provided is a method of removing at least a part of a carbon based material layer formed inside of a processing chamber for fabricating a semiconductor device including: generating an oxygen plasma; contacting oxygen plasma with the carbon-based material layer formed inside the processing chamber to form a carbon oxide; and purging the processing chamber of the carbon oxide.

### BRIEF DESCRIPTION OF THE DRAWINGS

Exemplary embodiments of the inventive concept will be more clearly understood from the following detailed description taken in conjunction with the accompanying drawings in which:

FIG. 1 is a flowchart of a method of fabricating a semiconductor device, according to embodiments of the inventive concept.

FIG. 2A is a plan view of a processing chamber used according to an embodiment;

FIG. 2B is a cross-sectional view of the processing chamber, taken along a line II-II′ shown in FIG. 2A, for explaining the method of fabricating the semiconductor device, according to embodiments of the inventive concept.

FIGS. 3A through 3E are side cross-sectional views of the substrate for snowing a patterning method for fabricating the semiconductor device according to an order, according to embodiments of the inventive concept.

FIG. 4 is a conceptual diagram of a cross-section of an inside of the processing chamber for showing a state when a carbon-based material, discharged from a carbon-based sacrificial layer pattern, is adsorbed onto the inside of the processing chamber.

FIG. 5 is a cross-sectional view of the substrate for showing a width of a line pattern of a sacrificial layer and a space between lines in a line pattern of the sacrificial layer, according to embodiments of the inventive concept.

FIG. 6 is a cross-sectional view of inside of the processing chamber for illustrating applying of oxygen gas and radio frequency (RF) power to the inside of the processing chamber so as to remove a carbon-based material layer formed inside the processing chamber, according to embodiments of the inventive concept.

FIG. 7 is a cross-sectional view of inside of the processing chamber for illustrating supplying of oxygen plasma, obtained from outside of the processing chamber, to inside of the processing chamber so as to remove a carbon-based material layer formed inside the processing chamber, according to embodiments of the inventive concept.

FIG. 8 is a graph showing a change in a yield rate by comparing before removing of a carbon-based material layer, formed inside a processing chamber, is performed to after removing of the carbon-based material layer is performed, according to embodiments of the inventive concept.

FIG. 9 is a flowchart of a method of cleaning a processing chamber in a semiconductor device, according to embodiments of the inventive concept.

FIG. 10 is a schematic diagram of a memory system included in a semiconductor device provided as an example that may be implemented by using a method of forming a micro-pattern, according to embodiments of the inventive concept.

### DETAILED DESCRIPTION OF THE EMBODIMENTS

As used herein, the term “and/or” includes any and all combinations of one or more of the associated listed items. Expressions such as “at least one of”, when preceding a list of elements, modify the entire list of elements and do not modify the individual elements of the list.

Hereinafter, embodiments will be described more fully with reference to the accompanying drawings, in which embodiments are shown. Embodiments may, however, be embodied in many different forms and should not be construed as limited to the embodiments set forth herein. Rather, these embodiments are provided so that this disclosure will be thorough and complete, and will fully convey the scope of the embodiments to those of ordinary skilled in the art. Like reference numerals in the drawings denote like elements. Various elements and areas in the drawing are schematically illustrated. Accordingly, embodiments are not limited to relative sizes or spaces shown in the drawing.

The terminology used herein is for the purpose of describing particular embodiments only and is not intended to be limiting of the embodiments. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, numbers, steps, operations, elements, components, or a combination thereof, but do not preclude the presence or addition of one or more other features, numbers, steps, operations, elements, components, or a combination thereof.

Unless otherwise defined, all terms including technical and scientific terms used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Meanwhile, when an exemplary embodiment can be differently implemented, a function or an operation specified in a particular process may be performed differently from an order specified in a flowchart. For example, two continuous processes may be substantially simultaneously performed, or processes may be performed in a reverse order according to a related function or operation.

In the, drawings, for example, illustrated shapes may be deformed according to fabrication technology and/or tolerances. Therefore, the embodiments are not limited to certain shapes illustrated in the present specification, and may include modifications of shapes caused in fabrication processes. Additionally, the term ‘substrate’ may refer to a substrate, or a laminated structure that, includes a substrate and certain layers or films formed on the substrate. Additionally, “a surface of a substrate”, described herein, may refer to an exposed surface of the substrate, or an outer surface of a certain layer or film formed on the substrate.

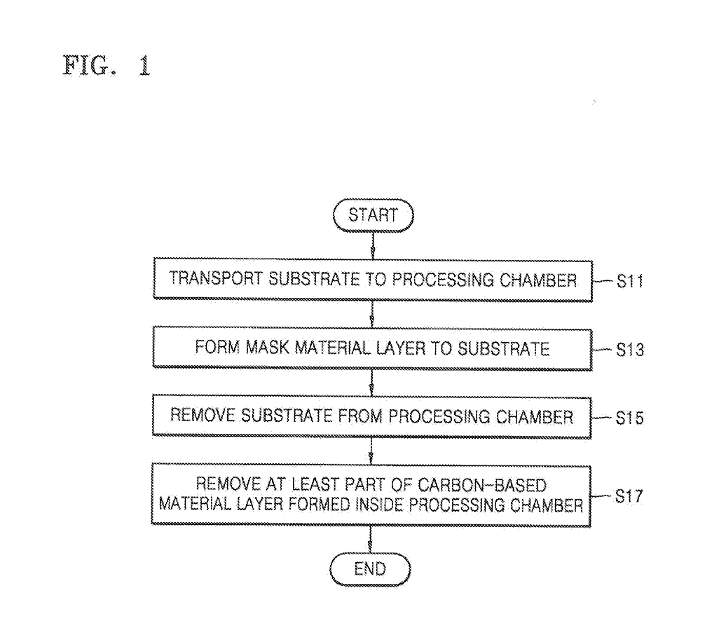

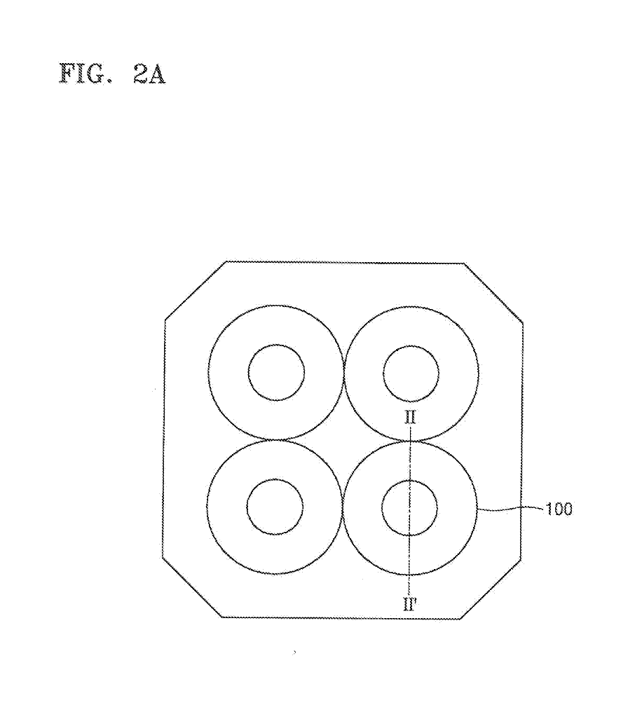

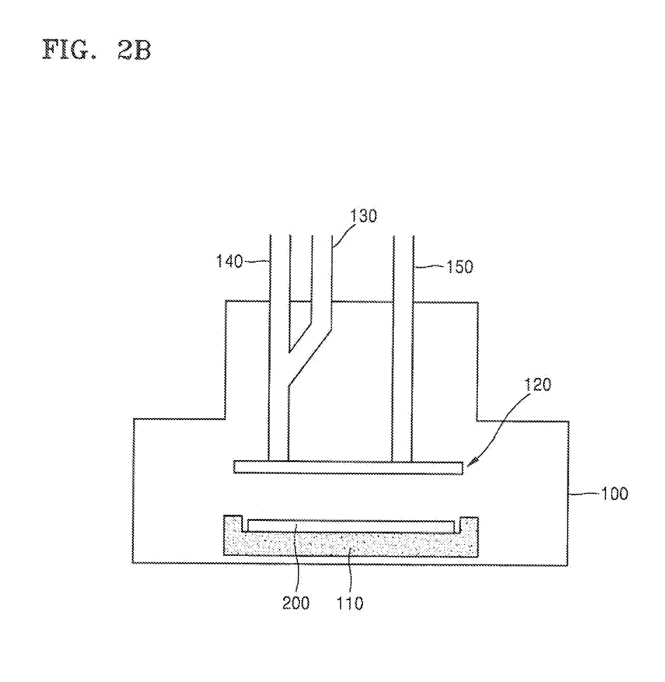

FIG. 1 is a flowchart of a method of fabricating a semiconductor device, according to embodiments of the present inventive concept. FIG. 2A is a plan view of a processing chamber according to an embodiment. FIG. 2B is a cross-sectional view of the processing chamber, taken along a line II-II′ shown in FIG. 2A, for explaining the method of fabricating the semiconductor device, according to embodiments of the present inventive concept.

The processing chamber 100 may include a susceptor 110 in which the substrate 200 transported to the processing chamber 100 is seated, a source supply hole 130 through which a source flows into the processing chamber 100, a cleaning gas supply hole 140 through which a cleaning gas flows into the processing chamber 100, a distribution plate 120 for uniformly distributing gases, which have flown into the processing chamber 100, to inside of the processing chamber 100, and an exhaust hole 150 for discharging a gas, which is generated due to a reaction, to outside of the processing chamber 100.

A space independent from outside may be formed in the processing chamber 100, so as to smoothly perform a process. The exhaust hole 150 is formed in the processing chamber 100, and a vacuum pump may be connected to the exhaust hole 150. As air inside the processing chamber 100 is pumped according to operation of the vacuum pump, a low-vacuum state or a high-vacuum state, may be maintained inside the processing chamber 100.

Referring to FIGS. 1 and 2B, in operation S11, a semiconductor 200 having a carbon-based sacrificial layer may be transported to the inside of the processing chamber 100. The substrate 200 may be transported to the processing chamber 100, and seated in the susceptor 110.

A plurality of processing chambers 100 may be spread out around a transfer chamber, from which a substrate is transferred, to connect to each other, and thus, form a cluster type. In such a structure, a robot in the transfer chamber may transfer the substrate 200 to the processing chamber 100. The substrate 200 may be transferred to inside of the processing, chamber 200 by the robot so as to perform a process and, for this, a gate may be formed at a side of the processing chamber 100.

A seat in which the substrate 200 is seated is provided to the susceptor 110, and the substrate 200 may be seated in the seat of the susceptor 110. The susceptor 110 may support the substrate 200, and fix the substrate 200 while the process is performed. As an example, the susceptor 110 may fix the substrate 200 by using a method performed by using vacuum. As another example, the susceptor 110 may fix the substrate 200 by using a method performed by using static electricity.

The susceptor 110 may function as one of two electrodes for forming plasma. Additionally the susceptor 110 may be formed of a material that absorbs electromagnetic energy and converts the absorbed electromagnetic energy into heat. The susceptor 110 may move upwards or downwards, or rotate for driving.

A surface of the substrate 200 may contact the seat of the susceptor 110, and the other surface of the substrate 200 may be exposed to air. If a process of depositing a mask material layer starts, the mask material layer may be deposited on the other surface of the substrate 200 which is exposed to air.

The substrate 200 may include a semiconductor material, for example, a group IV semiconductor, a group III-V compound semiconductor, or a group II-VI oxide semiconductor. For example, the group IV semiconductor may include silicon, germanium, or silicon-germanium. The substrate 200 may be provided as a bulk wafer or an epitaxial layer. Alternately, the substrate 200 may be formed of a semiconductor substrate such as a silicon-on-insulator (SOI) substrate, a gallium-arsenic substrate, a silicon germanium substrate, or the like. For example, unit devices that are needed to form a semiconductor device, such as various types of an active device or a passive device, may be formed on the substrate 200. The substrate 200 may be, selectively, an insulator substrate formed of silicon dioxide (SiO2) or other inorganic oxides, a glass substrate, or the like.

In operation S13, a mask material layer may be formed on the substrate 200 by supplying a source for deposition to inside of the processing chamber 100 via the source supply hole 130, and spraying the source onto the substrate 200 through the distribution plate 120.

The mask material layer may be used to form a pattern for etching a layer to be etched which is located below the mask material layer. The layer to be etched may be formed on the substrate 200. The substrate 200 and the layer to be etched may be formed of a same material, or different materials from each other. If the substrate 200 and the layer to be etched are formed of different materials from each other, the substrate 200 and the layer to be etched may have a same etching rate, etching rates similar to each other, or etching rates different from each other.

If the mask material layer is formed, the substrate 200 may be removed from the processing chamber 100 in operation S15. If the process of deposition with respect to the substrate 200 is finished, a robot may remove the substrate 200 through a gate at a side of the processing chamber 100.

Then, in operation S17, a process of removing at least a part of a carbon-based material layer, formed inside the processing chamber 100, may be performed. After the method of fabricating the semiconductor device is performed, a method of cleaning a processing chamber in the semiconductor device may be performed.

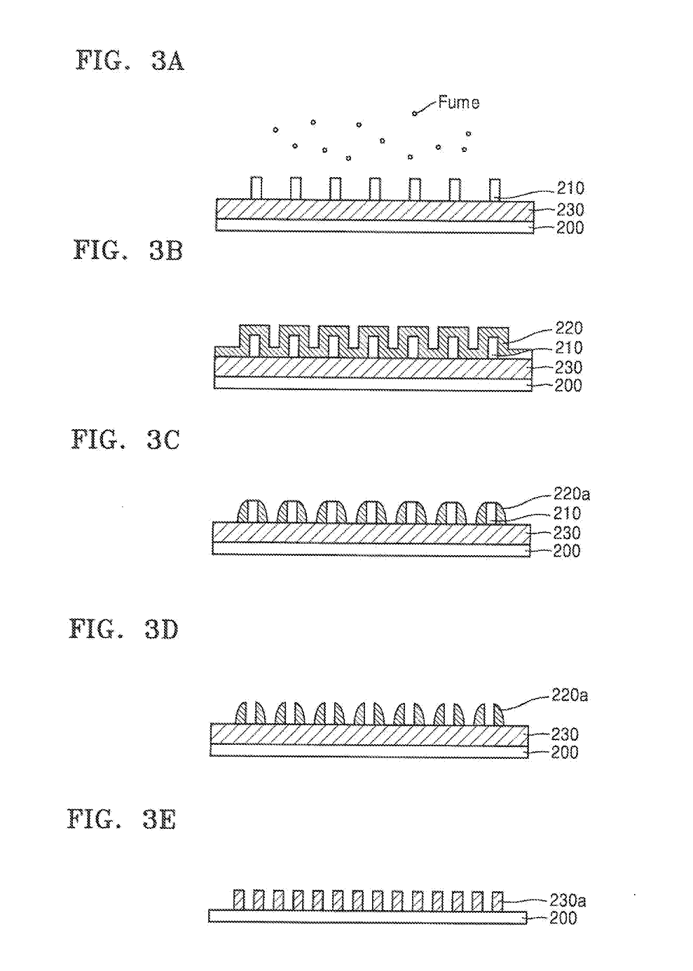

FIGS. 3A through 3E are side cross-sectional views of the substrate 200 for showing a patterning method for fabricating the semiconductor device according to an order, according to embodiments of the present inventive concept. FIG. 3A is a cross-sectional view of the substrate 200 having a carbon-based sacrificial layer pattern 210 before the substrate 200 is transported to the processing chamber 100. In some embodiments of the present inventive concept, the carbon-based sacrificial layer is provided on a layer 230 to be etched that is disposed on the substrate. FIG. 3B is a cross-sectional view of the substrate 200 for showing forming of a mask material layer 220 in the processing chamber 100. FIG. 3C is a cross-sectional view of the substrate 200 on which a spacer 220a is formed by performing an etching process after the substrate 200 is removed from the processing chamber 100. FIG. 3D is a cross-sectional view of the substrate 200 after the sacrificial layer pattern 210 is removed. FIG. 3E is a cross-sectional view of the substrate 200, onto which a micro-pattern 230a is transferred by etching the layer 230 while using the spacer 220a as an etching mask.

Referring to FIG. 3A, after the substrate 200 having the carbon-based sacrificial layer pattern 210 is transported to the processing chamber 100, a contaminating fume may be emitted from the carbon-based sacrificial layer pattern 210, and thus, spread throughout inside of the processing chamber 100. The carbon-based sacrificial layer pattern 210 of the substrate 200 may be formed of a spin-on hardmask (SOH) or an amorphous carbon layer (ACL). Since the fume is generated from the SOH or the ACL, the fume may be easily spread to outside. A main component of the fume emitted from the carbon-based sacrificial layer pattern 210 may be or include carbon.

The carbon-based sacrificial layer pattern 210 may be formed by using a photolithography process. In other words, after a carbon-based sacrificial layer is deposited on the layer 230 to be etched, a photoresist layer is formed on the carbon-based sacrificial layer, and then, the photoresist layer may be exposed to light via an exposure mask. After the photoresist layer is exposed to light, the photoresist layer is developed, and thus, a photoresist pattern may be formed on the carbon-based sacrificial layer. Then, the carbon-based sacrificial layer pattern 210 may be obtained by performing anisotropic etching on the carbon-based sacrificial layer by using the photoresist pattern as an etching mask. Then, the photoresist pattern, which is present on the carbon-based sacrificial layer pattern 210, may be easily removed by using a method such as an ashing method.

The carbon-based sacrificial layer, particularly, the carbon-based sacrificial layer formed of an SOH material may be formed by forming an organic compound layer by applying an organic compound to the layer 230 to be etched by using a spin coating process or other deposition processes, and then, performing a baking process at least once. The organic compound may include a hydrocarbon compound that includes an aromatic ring such as phenyl, benzene, or naphthalene, or a derivative thereof. Additionally, the organic compound may be formed of a material that contains a large amount of carbon, for example, about 85 to 99 weight % carbon with respect to a total weight of the organic compound. In detail, the organic compound layer may be formed on the layer 230 to be etched by applying the organic compound to the layer 230 to be etched by using a spin coating method or the like. Then, a carbon containing layer may be formed by primarily baking the organic compound layer at a temperature of about 150 to 350° C. The primary baking may be performed for about 60 seconds. Then, a carbon-based sacrificial layer formed of an SOH material may be formed by secondarily baking, and thus, hardening the carbon containing layer at a temperature of about 300 to 550° C. The secondary baking may be performed for about 30 to 300 seconds. As such, the carbon-based sacrificial layer formed of an SOH material is formed by hardening the carbon-containing layer by performing a secondary baking process. Thus, if another layer is formed on the carbon-based sacrificial layer, even if a deposition process is performed at a high temperature of about 400° C. or higher, an adverse effect may not be exerted on the carbon-based sacrificial layer in the deposition process. The carbon-based sacrificial layer formed of an SOH material may be easily removed by performing en aching or stripping process. The carbon-based sacrificial layer may be formed of an ACL material instead of the SOH material. Since the ACL material also contains a large amount of carbon, the ACL material may have characteristics similar to those of the SOH material. However, the carbon-based sacrificial layer pattern 210 is not limited to being formed of an SOH or ACL carbon layer, and a process of generating a carbon-based sacrificial layer formed of the SOH material is only an example, and embodiments are not limited to the process of generating a carbon-based sacrificial layer formed of the SON material.

Referring to FIG. 3B, the mask material layer 220 may be formed on a sidewall and a top surface of the carbon-based sacrificial layer pattern 210 in the processing chamber 100, so as to have a uniform thickness. The mask material layer 220 also covers exposed surfaces of the layer 230 to be etched, with uniform thickness. The mask material layer 220 may be formed of a material having etching selectivity with respect to the carbon-based sacrificial layer pattern 210 and the layer 230 to be etched. As an example, the mask material layer 220 may be formed of silicon dioxide, silicon nitride, silicon oxynitride, or a combination thereof.

The processing chamber 100 may be a processing chamber for performing atomic layer deposition (ALD) by using silicon dioxide, silicon nitride, silicon oxynitride, or a combination thereof.

In the current embodiment, a deposition process performed by using an ALD processing chamber, which is to be described hereinafter, may be performed according to a cycle as follows:

In a first step, if a precursor of a material, which is to be deposited, is supplied to inside of a processing chamber of an ALD apparatus, the precursor is chemically adsorbed onto a surface of a substrate. If an atomic layer formed of the precursor is deposited on a surface of the substrate by using such a chemical adsorption reaction, even if excessive precursors are supplied to the inside of the processing chamber, no further adhesion occurs. In a second step, when the precursor does not further react with the surface of the substrate, excessive precursors are removed to outside of the processing chamber by using inert gas. In a third step, after precursors are completely removed from the inside of the processing chamber, a reactant that may react with the precursor, and thus, form a material layer of a monolayer is supplied to the inside of the processing chamber. The supplied reactant performs a chemical adsorbing reaction with the precursor which is chemically adsorbed onto the surface of the substrate. After the atomic layer is deposited on the precursor by using a reactant through such a chemical adsorption reaction, even if excessive reactants are supplied to the inside of the processing chamber, no further adhesion occurs. In a fourth step, when the reactant does not further react with the surface of the substrate, excessive reactants are removed to outside of the processing chamber by using insert gas.

If another atomic layer, formed by using an additional reactant, is to be further deposited on the atomic layer, the method and steps described above may be employed.

A process of the first through fourth steps is referred to as a cycle. An atomic layer having a thickness that a user desires may be deposited on a substrate by repeatedly performing the cycle. As described above, a chemical adsorption reaction according to a self-limiting reaction needs to be normally performed so as to grow an atomic layer having a thickness that a user wants on a substrate.

Referring to FIG. 3C, the mask material layer 220 is anisotropically etched, and thus, the spacer 220a is formed at a sidewall of the carbon-based sacrificial layer pattern 210. The anistropic etching may be repeatedly performed until a surface of the layer 230 to be etched is exposed, so as to form the spacer 220a. An etching process may be performed in the processing chamber 100, but is not limited thereto.

Referring to FIG. 3D, the carbon-based sacrificial layer pattern 210 may be removed from the substrate 200 under conditions that etching of the spacer 220a and the layer 230 to be etched is controlled. In this case, since the carbon-based sacrificial layer pattern 210 is formed of a carbon-containing material, the carbon-based sacrificial layer pattern 210 may be easily removed by using a method such as an aching method. Resultantly, the spacer 220a remains on the layer 230 to be etched.

Referring to FIG. 3E, the layer 230 to be etched may be etched by using the spacer 220a as an etching mask, and thus, the micro-pattern 230a may be obtained. If the layer 230 to be etched is formed of a conductive material, a conductive pattern may be obtained. However, alternatively, if the layer 230 to be etched is an additional hardmask material layer, a new hardmask pattern may be obtained, and a lower layer that is located below the layer 230 to be etched may be further etched by using the new hardmask pattern. For example, the method described with reference to FIGS. 3A-3E may be employed. One of ordinary skill in the art may form a plurality of trenches having various widths on a semiconductor substrate by using the method described with reference to FIGS. 3A-3E, bury an insulating material in the plurality of trenches, and thus, define an active area.

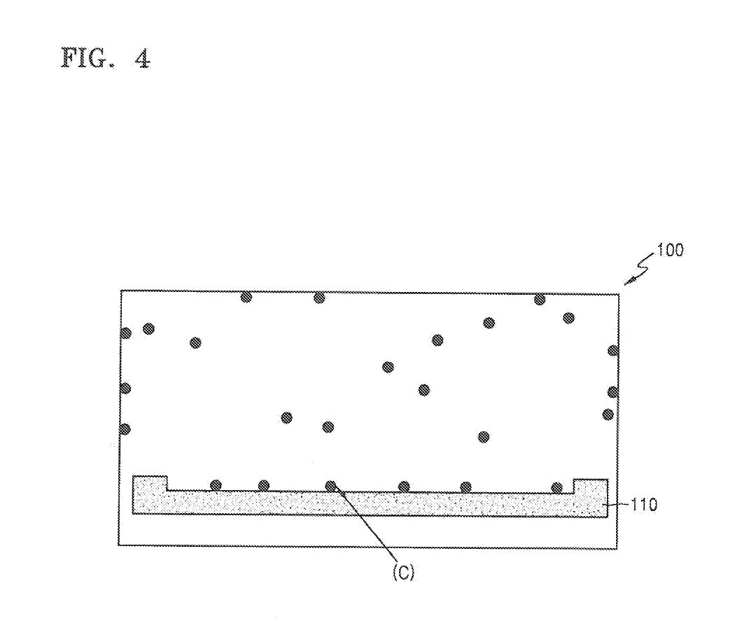

FIG. 4 is a conceptual diagram of a cross-section of an inside of the processing chamber 100 for showing a state when a carbon-based material, discharged from the carbon-based sacrificial layer pattern 210, is adsorbed onto the inside of the processing chamber 100. Carbon C, shown in FIG. 4, denotes carbon-based materials, and does not refer to just carbon.

After a substrate is discharged from the processing chamber 100, the carbon C emitted from the carbon-based sacrificial layer pattern 210 is adsorbed onto a sidewall of the processing chamber 100 and the susceptor 110, thus locally forming a carbon-based material layer inside the processing chamber 100. In other words, a carbon-based material layer formed inside the processing chamber 100 may be a material layer originated from the carbon-based sacrificial layer 210 of the substrate.

In the method of fabricating the semiconductor device, a deposition cycle that includes transporting of the substrate to the processing chamber, forming of the material layer, and removing of the substrate may be performed a plurality of times, after which, removing of the carbon-based material layer may be performed. The degree to which a carbon-based material layer is formed in the processing chamber may vary according to the process of fabricating the semiconductor device. Accordingly, the number of times the deposition cycle is performed may be vary according to a degree to which the carbon-based material layer is formed, and after the deposition cycle is performed for a plurality of times, the removing of the carbon-based material layer may be performed.

The forming of the carbon-based material layer is not limited to covering the whole processing chamber 100 with a carbon-based material, but includes adsorbing a carbon-based material onto a part of the processing chamber 100.

If the substrate 200 transported to the processing chamber 100 is seated in the susceptor 110, the carbon-based material layer, which has been adsorbed onto the susceptor 110, may be adsorbed onto the substrate 200. After the substrate 200 of which the carbon-based material layer is adsorbed onto a rear side is removed to outside of the processing chamber 100, a photolithography process may be performed. In this case, defocusing in an optical system may be caused by the carbon-based material layer adsorbed onto the rear surface of the substrate 200, and consequently, the yield rate in the fabrication of semiconductor devices may be reduced.

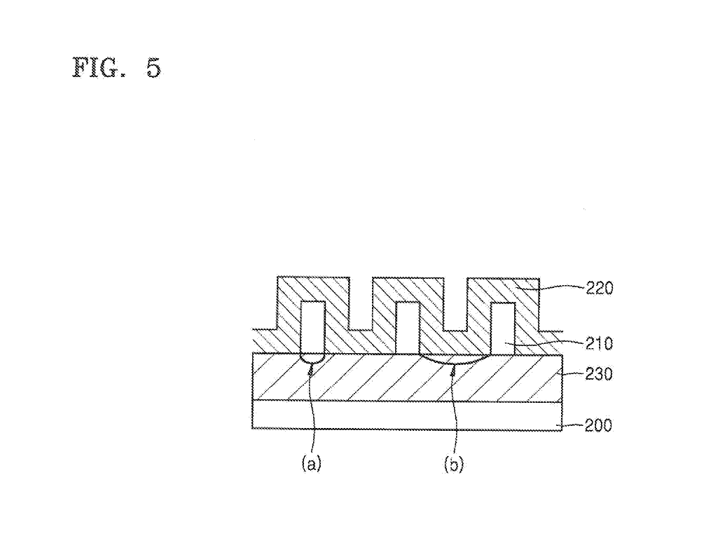

FIG. 5 is a cross-sectional view of the substrate 200 for showing a width a of a line pattern of the carbon-based sacrificial layer 210 and a space b between lines in a line pattern of the carbon-based sacrificial layer 210. The carbon-based sacrificial layer 210 may have a line pattern and a space pattern, and the space b between lines in the line pattern of the carbon-based sacrificial layer 210 may be three times the width a of lines in the line pattern of the carbon-based sacrificial layer 210. When the line pattern and the space pattern of the carbon-based sacrificial layer 210 are such that the space b between the lines in the line pattern is three times the width a of the lines in the line pattern, a critical dimension (CD) in a double patterning technology (DPT) process is equal to that in a quarter patterning technology (QPT) process. Since the DPT process and the QPT process include generating a mask material layer for a plurality of times, a carbon-based material layer that emits a contaminating fume may be formed inside the processing chamber. Additionally, the processing chamber in which a carbon-based material layer is formed is used for a plurality of times, a carbon-based material layer may be adsorbed onto the rear surface of the substrate 200 that is transported to the inside of the processing chamber. Accordingly, removing of at least a part of the carbon-based material layer may be needed.

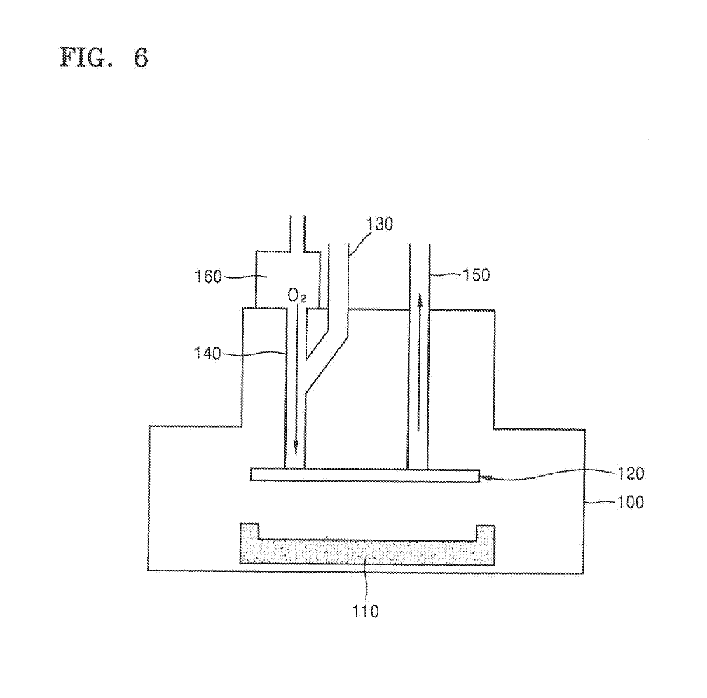

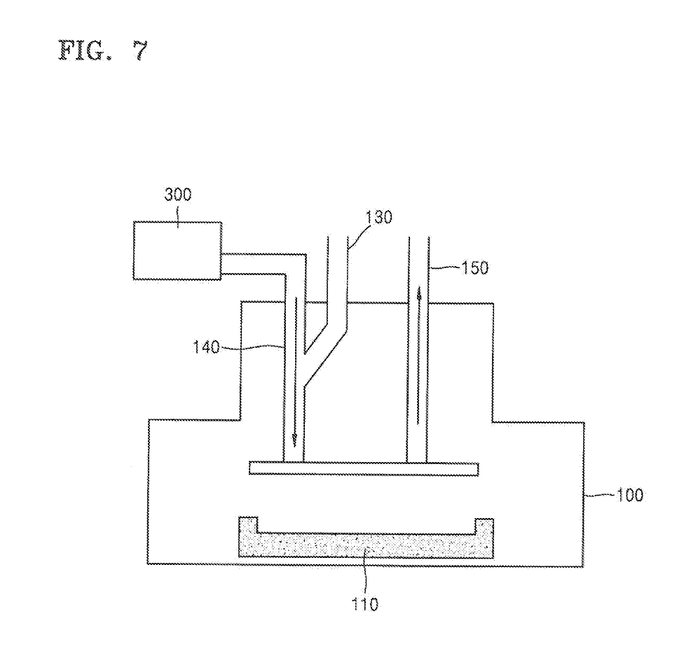

FIG. 6 is a cross-sectional view of inside of the processing chamber 100 for showing applying of oxygen gas and radio frequency (RF) power to the inside of the processing chamber 100 so as to remove a carbon-based material layer formed inside the processing chamber 100. FIG. 7 is a cross-sectional view of inside of the processing chamber 100 for snowing supplying of oxygen plasma, obtained from outside of the processing chamber 100, to inside of the processing chamber 100 so as to remove a carbon-based material layer formed inside the processing chamber 100.

Referring to FIG. 6, oxygen gas may be supplied to the inside of the processing chamber 100 via a cleaning gas supply hole 140, and then, RF power may be applied to the susceptor 110 and the distribution plate 120 via an RF power port 160. A pair of conductive flat-panel electrodes, which face each other and extend in parallel with each other, may be provided inside the processing chamber 100. Plasma may be excited between the pair of conductive flat-panel electrodes, by applying RF power to one of the pair of conductive flat-panel electrodes and grounding the other electrode. A process of generating the plasma may be performed for about 0.5 second to 3 seconds. However, a time period for which the process of generating plasma is performed may be changed according to a size and a shape of the processing chamber 100, a magnitude of the RF power, or the like.

If oxygen plasma is generated by the RF power, oxygen radicals (O radicals) may combine with a carbon-based material layer inside the processing chamber 100, particularly, a carbon-based material layer on an upper surface of the susceptor 110, and thus, form carbon oxide. The carbon oxide may be discharged to outside of the processing chamber 100 via the exhaust hole 150. Accordingly, the carbon-based material layer inside the processing chamber 100 may be removed. The carbon oxide may include carbon monoxide, carbon dioxide, or the like.

Referring to FIG. 7, oxygen plasma is generated outside the processing chamber 100, the oxygen plasma may be supplied to inside of the processing chamber 100, and thus, a carbon-based material layer inside the processing chamber 100 may be removed. As such, if a remote plasma method performed by generating plasma outside the processing chamber 100 is employed, the efficiency of removing the carbon-based material layer may be lower than that of removing the carbon-based material layer by generating oxygen plasma inside of the processing chamber 100. However, if plasma generated according, to the remote plasma method is used, damage to the processing chamber 100 may be prevented. A method of using a plasma generator 300, shown in FIG. 7 is only an example of generating O radicals outside the processing chamber 100, and embodiments are not limited thereto. The process of removing the carbon-based material layer by using oxygen plasma is described above with reference to FIG. 6.

Hereinafter, construction and effect of embodiments are described in detail by comparing a fabrication example to a comparison example. However, the fabrication example is provided so as to gain a sufficient understanding of the embodiments, but does not limit a scope of embodiments.

<Fabrication Example>

RF power of 400 W is applied to the inside of a processing chamber, and an oxygen gas flow rate of 500 Sccm and a pressure of 2.0 Torr (a pressure of 1.8 Torr inside the processing chamber 100) are supplied to the inside of the processing chamber 100, so as to remove a carbon-based material layer formed inside the processing chamber.

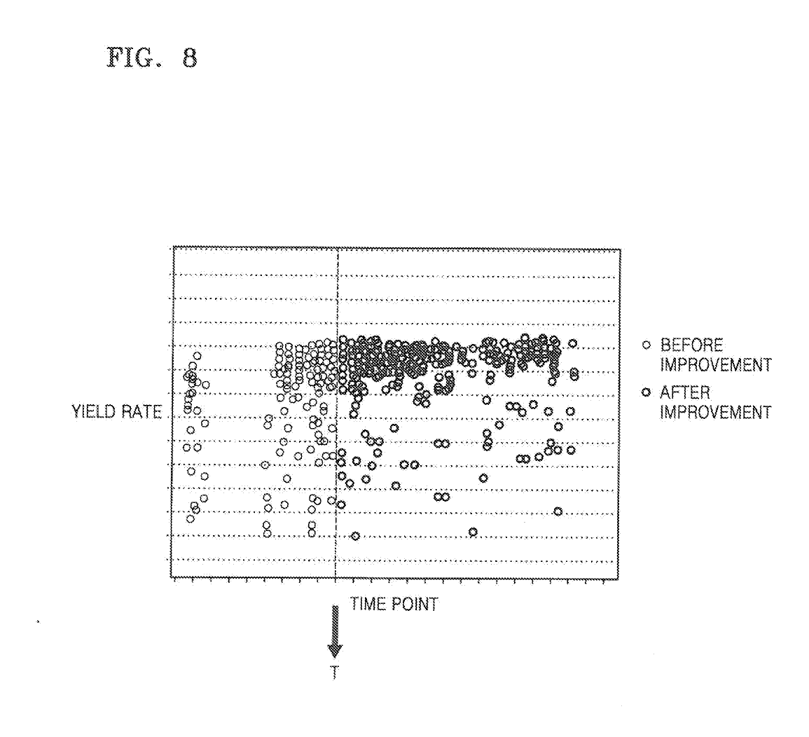

FIG. 8 shows a change in a yield rate according to the comparison example that does not include the removing of the carbon-based material which is formed inside the processing chamber, and the fabrication example. If all of or at least a part of the carbon-based material layer inside the processing chamber is removed, all of or at least a part of the carbon-based material that has been adsorbed onto the susceptor may be also be removed. Even if a new substrate is transported to the processing chamber and contacts the susceptor, the carbon-based material may be prevented from being adsorbed onto a rear surface of the substrate or only a small amount of the carbon-based material may be adsorbed onto the processing chamber. Accordingly, the degree of accuracy in a photolithography process may improve, and thus, a yield rate may increase.

Referring to FIG. 8, it may be understood that the yield rate has increased on average after the removing of the carbon-based material layer formed inside the processing chamber, is further performed (after a time point T). Additionally, it may be understood that a low yield rate in the production of substrates may decrease as the carbon-based material layer is further removed. Results show that yield rate increases by 0.9% on average when the embodiment is performed, compared to when the embodiment is not performed.

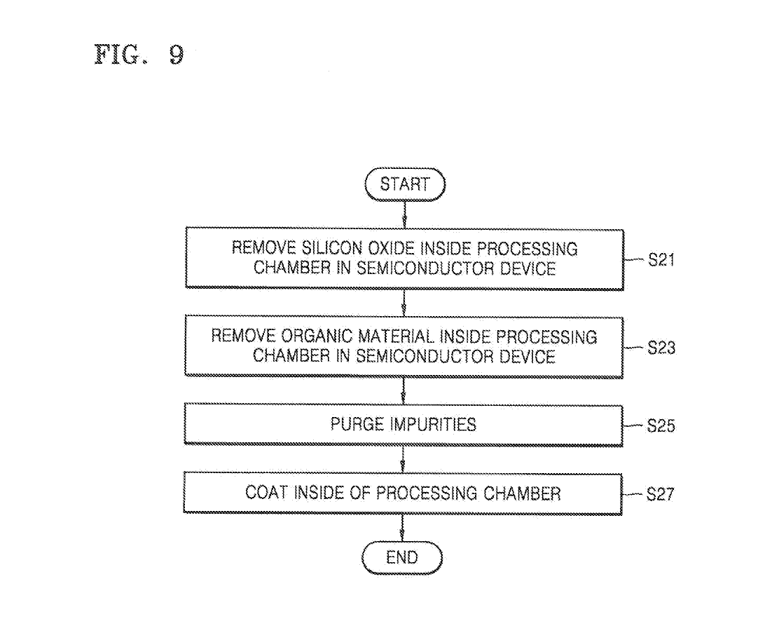

FIG. 9 is a flowchart of a method of cleaning a processing chamber for fabricating a semiconductor device, according to embodiments of the present inventive concept.

Referring to FIG. 9, in operation S21 silicon oxide inside the processing chamber for fabricating a semiconductor device may be removed. The silicon oxide may be removed by using nitrogen trifluoride (NF3).

The NF3 may be supplied the inside of the processing chamber via a cleaning gas supply hole, and sprayed into the processing chamber through a distribution plate. RF power may be applied to a susceptor and a distribution plate via an RF power port inside the processing chamber. NF3 gas may be activated by using plasma generated by using the RF power. The silicon oxide inside the processing chamber may be removed according to an oxidation-reduction reaction between the silicon oxide inside the processing chamber and activated fluoride.

Additionally, fluoride radicals or ions may be introduced into the processing chamber, and thus, react with the silicon oxide inside the processing chamber so as to clean the processing chamber. The fluoride radicals, and the silicon oxide inside processing chamber may react with each other, and thus, volatile silicon tetrafluoride (SiF4) gas, oxygen gas, or the like may be formed. However, the gas used to remove the silicon oxide is not limited to NF3, and may be a gas obtained by mixing the NF3 with another gas.

In operation S23, an organic material inside the processing chamber for fabricating a semiconductor device may be removed. The organic material may be removed by using oxygen plasma. The organic material may be or include carbon.

The oxygen plasma may be generated by supplying oxygen gas and applying RF power to inside of the processing chamber. Additionally, the oxygen plasma may be generated from outside of the processing chamber, and supped to the inside of the processing chamber. If a remote plasma method performed by generating plasma from outside of the processing chamber is employed, the efficiency of removing the carbon-based material layer may deteriorate, but may prevent damage to the processing chamber.

If oxygen plasma is generated by using the RF power, the O-radicals may combine with an organic material inside the processing chamber, and thus, form carbon oxide. The carbon oxide may be discharged to the outside of the processing chamber via an exhaust hole, and thus, the organic material inside the processing chamber may be removed. The carbon oxide may include carbon monoxide, carbon dioxide, or the like.

In operation S25, impurities, generated in the removing of the silicon oxide inside the processing chamber and the removing of the organic material inside the processing chamber, may be purged. In the purging of the impurities, silicon fluoride (SiFx) that was generated in the removing of the silicon oxide, carbon oxide (COx) that was generated in the removing of the organic material, or the like may be purged via an exhaust hole in the processing chamber. The purging of the impurities may be performed for at least about 0.5 second or 2 seconds. However, a time period for which the purging of the impurities is performed may vary according to a size of the processing chamber, performance of a pump, or the like.

In the processing chamber, a thin-film deposition, process of depositing a dielectric material or the like on the substrate, a photolithography process of exposing or covering an area selected from thin-films by using a photosensitive material, an etching process of removing a thin film in the selected area and patterning the substrate, or the like may be performed.

In operation S27, the inside of the processing chamber may optionally be coated by using silicon oxide, silicon nitride, silicon oxynitride, or a combination thereof, after purging of the impurities is performed. The coating of the inside of the processing chamber is performed so as to establish an environment suitable to form a mask material layer formed of silicon oxide, silicon nitride, silicon oxynitride, or a combination thereof. However, in some embodiments, coating of the inside of the processing chamber may not be performed.

Accordingly, the processing chamber, cleaned according to embodiments of the present inventive concept, may be a processing chamber used to deposit silicon oxide, silicon nitride, silicon oxynitride, or a combination thereof on a substrate as an atomic layer.

After the method of cleaning the processing chamber for fabricating semiconductor device is performed, a new substrate may be transported to the processing chamber, and then, the method of fabricating a semiconductor device may be performed. In other words, after operation 827 described with reference to FIG. 9 is performed, operation S11 described with reference to FIG. 1 may be performed. Additionally, after the method of fabricating the semiconductor device is performed, the method of cleaning the processing chamber for fabricating a semiconductor device may be re-performed. In other words, after operation S17 described with reference to FIG. 1 is performed, operation S21 described with reference to FIG. 9 may be performed.

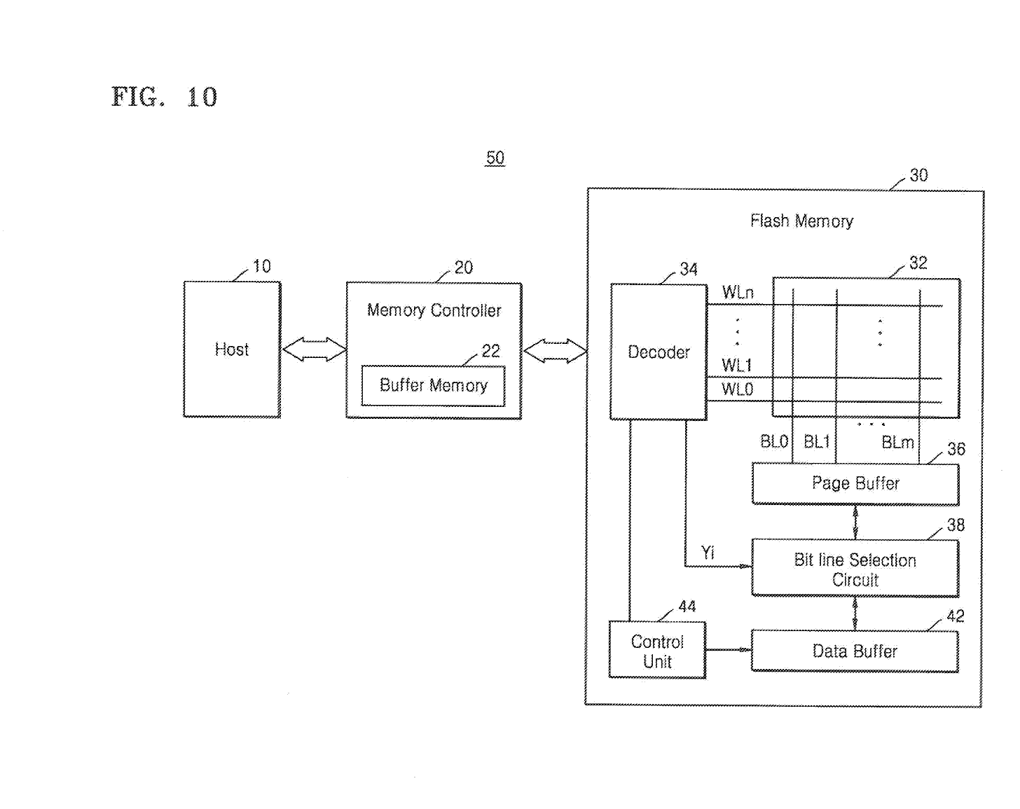

FIG. 10 is a schematic diagram of a memory system 50 included in a semiconductor device provided as an example that may be implemented by using a method of forming a micro-pattern, according to embodiments of the present inventive concept.

Referring to FIG. 10, the memory system 50 included in the semiconductor device may include a host 10, a memory controller 20, and a flash memory 30.

The memory controller 20 functions as an interface between the host 10 and the flash memory 30, and may include a buffer memory 22. Although not shown, the memory controller 20 may further include a central processing unit (CPU), a read-only memory (ROM), a random access memory (RAM), and interface blocks.

The flash memory 30 may further include a cell array 32, a decoder 34, a page buffer 36, a bit line selection circuit 38, a data buffer 42, and a control unit 44.

Data and a write command are input from the host 10 to the memory controller 20, and the memory controller 20 controls the flash memory 30 so that the data is written to the cell array 32 according to the write command input to the memory controller 20. Additionally, the memory controller 20 controls the flash memory 30 so that data stored in the cell array 32 is read according to a read command input from the host 10. The buffer memory 22 temporarily stores data transmitted between the host 10 and the flash memory 30.

The cell array 32 of the flash memory 30 consists of a plurality of memory cells. The decoder 34 is connected to, the cell array 32 via words lines WL0 through WLn. The decoder 34 receives an input of an address from the memory controller 20, and generates a selection signal Yi so as to select a word line from among the word lines WL0 through WLn or select a bit line from among bit lines BL0 through BLn. The page buffer 36 is connected to the cell array 32 via the bit lines BL0 through BLn.

While the inventive concept has been particularly shown and described with reference to exemplary embodiments thereof, it will be understood that various changes in form and details may be made therein without departing from the spirit and scope of the following claims.

What is claimed is:

1. A method of fabricating a semiconductor device, the method comprising:
transporting a substrate having a carbon-based sacrificial layer pattern to a processing chamber;
forming a mask material layer on the substrate;
removing the substrate from the processing chamber; and
removing at least a part of a carbon-based material layer formed inside the processing chamber.

2. The method of claim 1, wherein the mask material layer comprises silicon oxide, silicon nitride, silicon oxynitride, or a combination thereof.

3. The method of claim 1, wherein the carbon-based sacrificial layer pattern is formed of a spin-on hardmask (SOH) or an amorphous carbon layer (ACL).

4. The method of claim 1, wherein the carbon-based material layer is formed inside the processing chamber based on the carbon-based sacrificial layer pattern of the substrate.

5. The method of claim 1, wherein the carbon-based sacrificial layer pattern has a line pattern and a space pattern, and a space between lines in the line pattern of the carbon-based sacrificial layer pattern is three times a width of the line pattern of the carbon-based sacrificial layer pattern.

6. The method of claim 1, wherein the removing of the at least a part of the carbon-based material layer comprises removing the carbon-based material layer by supplying oxygen gas into and applying radio frequency (RF) power to the processing chamber.

7. The method of claim 1, wherein the removing of the at least a part of the carbon-based material layer comprises supplying oxygen plasma, obtained from outside of the processing chamber, into the processing chamber.

8. The method of claim 1, wherein the method comprises a deposition cycle that includes the transporting of the substrate, the forming of the mask material layer, and the removing of the substrate, and
the removing of the at least a part of the carbon-based material layer is performed after performing the deposition cycle a plurality of times.

9. A method of cleaning a processing chamber for fabricating a semiconductor device, the method comprising:
removing silicon oxide in e the processing chamber for fabricating a semiconductor device;
removing an organic material inside the processing chamber for fabricating a semiconductor device; and
purging impurities generated during the removing of the silicon oxide and the removing of the organic material, wherein the purging discharges the impurities from the processing chamber.

10. The method of claim 9, wherein the removing of the silicon oxide comprises using nitrogen trifluoride (NF₃).

11. The method of claim 9, wherein the removing of the organic material comprises using oxygen plasma.

12. The method of claim 11, wherein the oxygen plasma is generated by supplying oxygen gas into and applying radio frequency (RF) power to the processing chamber.

13. The method of claim 11, wherein the oxygen plasma is generated outside of the processing chamber and supplied into the processing chamber.

14. The method of claim 9, wherein the processing chamber is configured to perform atomic payer deposition (ALD) by using silicon oxide, silicon nitride, silicon oxynitride, or a combination thereof.

15. The method of claim 9, further comprising coating the inside of the processing chamber with silicon oxide, silicon nitride, silicon oxynitride, or a combination thereof, after the purging of the impurities is performed.

16. A method of removing at least a part of a carbon-based material layer formed inside of a processing chamber for fabricating a semiconductor device, the method comprising:
generating an oxygen plasma;
contacting the oxygen plasma with the carbon-based material layer formed inside of the processing chamber to form a carbon oxide; and
purging the processing chamber of the carbon oxide.

17. The method of claim 16, wherein the oxygen plasma is generated by supplying oxygen gas to inside the processing chamber and applying radio frequency (RF) power to the inside the processing chamber.

18. The method of claim 16, wherein the oxygen plasma is generated outside the processing chamber and supplied to inside the processing chamber.

19. The method of claim 16, wherein the processing chamber is configured to perform atomic layer deposition (ALD) using silicon oxide, silicon nitride, silicon oxynitride, or a combination thereof.

20. The method of claim 16, further comprising coating the inside of the processing chamber with silicon oxide, silicon nitride, or a combination thereof, after purging the processing chamber of the carbon oxide.
